(19) United States
(12) Patent Application Publication
(10) Pub. No.: US 2024/0347671 A1
(43) Pub. Date: Oct. 17, 2024

(54) LIGHT-EMITTING DIODE AND LIGHT-EMITTING DEVICE

(71) Applicant: Tianjin Sanan Optoelectronics Co., Ltd., Tianjin (CN)

(72) Inventors: Zhiwei WU, Tianjin (CN); Yanyun WANG, Tianjin (CN); Weiping XIONG, Tianjin (CN); Di GAO, Tianjin (CN); Huanshao KUO, Tianjin (CN); Yuren PENG, Tianjin (CN)

(21) Appl. No.: 18/735,244

(22) Filed: Jun. 6, 2024

Related U.S. Application Data
(63) Continuation of application No. PCT/CN2021/137175, filed on Dec. 10, 2021.

(51) Int. Cl. H01L 33/20; H01L 33/38

(52) U.S. Cl. CPC H01L 33/20; H01L 33/38

(57) ABSTRACT

A light-emitting diode and a light-emitting device are provided. In the light-emitting diode, a first mesa including an active layer satisfies a perimeter-to-area ratio

$$\frac{2 \sqrt{π s}}{s} \leq γ \leq \frac{2 ( ( \frac{s}{L 1} ) + L 1 )}{s}$$

under a same light-emitting area. Under the same light-emitting area of the active layer, an exposed portion on a sidewall of the first mesa is less, and thus problems of light absorption and non-radiative recombination caused by a defect of the sidewall of a small-sized light-emitting diode are reduced during working at a low current. In addition, a non-planar light-emitting surface can improve a light-emitting probability of the sidewall of the light-emitting diode, and an external light-emitting efficiency of the light-emitting diode is further improved.

### CROSS-REFERENCE TO RELATED APPLICATION

This application is a continuation of International Application No. PCT/CN2021/137175, filed on Dec. 10, 2021, which is herein incorporated by reference in its entirety.

### TECHNICAL FIELD

The disclosure relates to the field of semiconductor technology, and more particularly to a light-emitting diode (LED) and a light-emitting device.

### BACKGROUND

In recent years, light-emitting diodes (LEDs) have been widely used, and play an increasingly important role in the fields of various display systems, lighting systems, automotive taillights, etc.

The LEDs have advantages of low cost, high light efficiency, energy conservation, environmental protection, etc., and is widely applied to scenes such as illumination, visible light communication, and light-emitting display.

A structure of LED in the related art at least includes an epitaxial structure, and the epitaxial structure includes a first-type semiconductor layer, an active layer, and a second-type semiconductor layer stacked in sequence; and the first-type semiconductor layer and the second-type semiconductor layer are electrically connected to electrodes respectively. Specially, the active layer is also referred to as a light-emitting layer, and when the LED works, a positive voltage is applied to a connection end of a positive electrode, and a negative voltage is applied to a connection end of a negative electrode, so that the positive and negative voltages are loaded at two ends of the LED, thereby causing the active layer emitting light. Moreover, the active layer is usually a quantum-well structure.

In view of a small-sized LED (size less than 300 micrometers abbreviated as um) worked at a low current (i.e., 0.01 milliamperes abbreviated as mA to 1.5 mA), users have high requirements for external quantum efficiency of the small-sized LED. When the LED operates at the low current, problems of defect absorption and non-radiative recombination caused by the defect of an exposed sidewall of the LED becomes particularly prominent.

### SUMMARY

In order to reduce the problem of an excessive exposed area of the sidewall of the LED when the LED works at the low current as described above, in an aspect of the present disclosure, an embodiment provides a LED, including a first surface and a second surface that is disposed opposite to the first surface. The first surface includes a first side edge, a second side edge, a third side edge, and a fourth side edge that are sequentially connected in that order.

The LED further includes: an epitaxial structure, and the epitaxial structure includes: a first mesa and a second mesa, which are sequentially stacked from top to bottom in that order; the first mesa at least includes: a first-type semiconductor layer and an active layer, and the second mesa at least includes: a second-type semiconductor layer; and an area of an upper surface of the second mesa is greater than or equal to an area of a lower surface of the first mesa.

An area of a projection of the first mesa on a plane where the first surface is located is represented by s, and a perimeter-to-area ratio of the projection of the first mesa is represented by γ, and the perimeter-to-area ratio γ satisfies the following formula:

$$\frac{2 \sqrt{π s}}{s} \leq γ \leq \frac{2 ( ( \frac{s}{L 1} ) + L 1 )}{s}$$

L1 represents a projection length of an upper surface of the first mesa on a plane passing through the first side edge and perpendicular to the plane where the first surface is located.

Based on the above technical solution, a thickness of the first-type semiconductor layer is in a range of 2 micrometers (μm) to 5 μm; a thickness of the active layer is in a range of 0.02 μm to 0.07 μm; and a thickness of the second-type semiconductor layer is in a range of 3 μm to 11 μm.

Based on the above technical solution, a ratio of the area of the projection of the first mesa on the plane where the first surface is located to an area of a projection of the second mesa on the plane where the first surface is located is in a range of 0.02 to 0.6.

Based on the above technical solution, as viewed from a direction perpendicular to the first surface, a length of a part of a side edge of an outer contour of the upper surface of the first mesa parallel to the first side edge of the first surface of the LED is represented by L2, L1 is greater than L2, and at least one side edge of the projection of the first mesa on the plane where the first surface is located is an arc.

Based on the above technical solution, the projection of the first mesa on the plane where the first surface is located is a circle or an ellipse or a combined pattern of an arc and a straight line.

Based on the above technical solution, the projection of the second mesa on the plane where the first surface of the LED is located is a circle or an ellipse or a rounded rectangle.

Based on the above technical solution, a length of the first side edge is equal to a length of the third side edge, a length of the second side edge is equal to a length of the fourth side edge, and the length of the first side edge is greater than the length of the second side edge; a minimum distance from a portion in an outer contour of the upper surface of the second mesa closet to the first side edge or the third side edge of the first surface to a side edge of the upper surface of the first mesa is represented by D1; a minimum distance from a portion in the outer contour of the upper surface of the second mesa closet to the second side edge or the fourth side edge of the first surface to the side edge of the upper surface of the first mesa is represented by D2; and D1 is less than D2.

Based on the above technical solution, a minimum distance from the side edge of the upper surface of the first mesa to the first side edge or the third side edge of the first surface is in a range of 2 μm to 6 μm.

Based on the above technical solution, the first-type semiconductor layer is provided with a first contact electrode thereon, the first contact electrode includes: a first dot electrode and two first extension portions, and the two first extension portions respectively extend towards different side edges of the LED from the first dot electrode.

Based on the above technical solution, the two first extension portions form a straight-line segment or an arc-shaped segment.

Based on the above technical solution, when the two first extension portions form the arc-shaped segment, two ends of a projection of the arc-shaped segment on the first surface are located on a centerline of the projection of the first mesa on the first surface.

Based on the above technical solution, the second-type semiconductor layer is provided with a second contact electrode thereon, the second contact electrode is a dot electrode, or the second contact electrode includes: a second dot electrode and two second extension portions, and the two second extension portions respectively extend towards different side edges of the LED from the second dot electrode.

Based on the above technical solution, in a plane perpendicular to the first surface of the LED and passing through the fourth side edge, a projection length of the second contact electrode on the plane perpendicular to the first surface of the LED and passing through the fourth side edge is less than a projection length of the first contact electrode on the plane perpendicular to the first surface of the LED and passing through the fourth side edge.

Based on the above technical solution, the LED further includes: an insulation protection layer disposed on the upper surface of the first mesa and a sidewall of the epitaxial structure; a first pad electrode and a second pad electrode are disposed above the insulation protection layer; and the insulation protection layer defines a first opening and a second opening thereon; the first pad electrode is filled into the first opening to be electrically connected to the first-type semiconductor layer; and the second pad electrode is filled into the second opening to be electrically connected to the second-type semiconductor layer.

Based on the above technical solution, a first contact electrode is disposed between the first pad electrode and the first-type semiconductor layer, and a second contact electrode is disposed between the second pad electrode and the second-type semiconductor layer.

Based on the above technical solution, a bottom width of the first opening is less than or equal to a bottom width of the first contact electrode, and a bottom width of the second opening is less than or equal to a bottom width of the second contact electrode.

Based on the above technical solution, as viewed from a direction perpendicular to the first surface, partial regions of the first pad electrode and the second pad electrode overlap the active layer respectively, or the first pad electrode and the second pad electrode are disposed outside the active layer.

Based on the above technical solution, the LED further includes: a substrate and a bonding layer; the bonding layer is disposed between the substrate and the epitaxial structure; and the bonding layer is a single-layer structure or a composite-layer structure and is made of a conductive material or an insulation material.

Based on the above technical solution, a thickness of the bonding layer is in a range of 1 μm to 5 μm.

Based on the above technical solution, a size of the LED is less than 300 μm.

The present disclosure further provides a LED, including: a first surface and a second surface that is disposed opposite to the first surface. The first surface includes a first side edge, a second side edge, a third side edge, and a fourth side edge, which are sequentially connected in that order; and the LED further includes: an epitaxial structure, and the epitaxial structure includes: a first mesa and a second mesa that are sequentially stacked from top to bottom in that order; the first mesa at least includes: a first-type semiconductor layer and an active layer, and the second mesa at least includes: a second-type semiconductor layer; and an area of an upper surface of the second mesa is greater than or equal to an area of a lower surface of the first mesa; and a size of the LED is less than 300 μm, at least one side edge of a projection of the first mesa on a plane where the first surface is located is an arc, and a protrusion portion of the arc faces towards a side edge of the first surface of the LED closer to the arc.

In another aspect of the present disclosure, a light-emitting device is provided, which adopts the LED according to any of the above-mentioned LEDs.

According to the technical solution of the present disclosure, the first mesa containing the active layer satisfies the formula:

$$\frac{2 \sqrt{π s}}{s} \leq γ \leq \frac{2 ( ( \frac{s}{L 1} ) + L 1 )}{s} ,$$

thereby making the sidewall of the first mesa expose less under a same light-emitting area of the active layer to solve the problems of light absorption and non-radiative recombination caused by the sidewall defect during the small-sized LED working at the low current. In addition, a non-planar light-emitting surface can improve the light-emitting probability of the sidewall of the LED and further improve the external light-emitting efficiency of the LED.

According to the other technical solution of the present disclosure, in view of the LED with the size less than 300 μm, the at least one side edge of the projection of the first mesa on the plane where the first surface is located is the arc, so that the sidewall of the first mesa is exposed to be less under the same light-emitting area of the active layer, thereby solving the problems of light absorption and non-radiative recombination caused by the sidewall defect during the small-sized LED working at the low current. In addition, the arc-shaped light-emitting surface is the circle or the ellipse or the rounded rectangle, which can improve the light-emitting probability of the sidewall of the LED and further improve the external light-emitting efficiency of the LED.

### Beneficial Effects

The other features and advantages of the present disclosure will be elaborated in subsequent disclosure and will be partially apparent from the disclosure or understood through the implementation of the present disclosure. The objective and other advantages of the present disclosure can be achieved and obtained through the structures specifically pointed out in the disclosure and attached drawings.

### BRIEF DESCRIPTION OF DRAWINGS

In order to more clearly illustrate the embodiments of the present disclosure or the technical solutions in the related art, the attached drawings required in the description of the embodiments, or the related art will be briefly described below. Apparently, the attached drawings in the following description are some embodiments of the present disclosure, and for those skilled in the related art, other drawings may be obtained according to the attached drawings without creative efforts.

FIG. 1 illustrates a schematic cross-sectional view of a LED in the related art. FIG. 2 illustrates a schematic top view of the LED in the related art.

FIG. 3 illustrates a schematic diagram of a first mesa and a second mesa of the LED in the related art, where the first mesa and the second mesa are both rectangular structures.

FIG. 4 illustrates a schematic cross-sectional view of a LED according to an embodiment of the present disclosure.

FIG. 5 illustrates a schematic diagram of a projection of a first mesa to a plane where a first surface is located according to a first embodiment of the present disclosure.

FIG. 6 illustrates a schematic diagram of a projection of the first mesa to the plane where the first surface is located according to a second embodiment of the present disclosure.

FIG. 7 illustrates a schematic diagram of a projection of the first mesa to the plane where the first surface is located according to a third embodiment of the present disclosure.

FIG. 8 illustrates a schematic diagram of a projection of the first mesa to the plane where the first surface is located according to a fourth embodiment of the present disclosure.

FIG. 9 illustrates a schematic diagram of an optical path of light in the LED according to the embodiment of the present disclosure.

FIG. 10 illustrates a schematic diagram of a circle projection of a second mesa 10b to the plane where the first surface of the LED is located according to the embodiment of the present disclosure.

FIG. 11 illustrates a schematic diagram of an ellipse projection of a second mesa 10b to the plane where the first surface of the LED is located according to the embodiment of the present disclosure.

FIG. 12 illustrates a schematic diagram of a rounded rectangle projection of a second mesa 10b to the plane where the first surface of the LED is located according to the embodiment of the present disclosure.

FIG. 13 illustrates a schematic diagram of a first contact electrode and a second contact electrode of the LED according to an embodiment of the present disclosure.

FIG. 14 illustrates a schematic diagram of a first contact electrode and a second contact electrode of the LED according to another embodiment of the present disclosure.

FIG. 15 illustrates a schematic top view of the LED according to an embodiment of the present disclosure.

FIG. 16 illustrates a schematic cross-sectional view of the LED illustrated in FIG. 15 along a section line B-B′.

FIG. 17 illustrates a schematic top view of a LED according to another embodiment of the present disclosure.

FIG. 18 illustrates a schematic cross-sectional view of the LED illustrated in FIG. 17 along a section line C-C′.

FIG. 19 illustrates a schematic diagram of an optical test result according to an embodiment of the present disclosure.

Description of reference signs are as follows:

10a—first mesa; 10b—second mesa; 11—first-type semiconductor layer; 12—second-type semiconductor layer; 13—active layer; 100—first surface; 200—second surface; 31—first contact electrode; 31a—first dot electrode; 31b—first extension portion; 32—second contact electrode; 32a—second dot electrode; 32b—second extension portion; 40—insulation protection layer; 51—first pad electrode; 52—second pad electrode; 20—bonding layer; 60—substrate; 70—electricity-insulation layer; 40a—first opening; 40b—second opening; a—first side edge; b—second side edge; c—third side edge; d—fourth side edge.

### DETAILED DESCRIPTION OF EMBODIMENTS

In order to make the objectives, technical solutions, and advantages of the embodiments of the present disclosure clearer, the technical solutions in the embodiments of the present disclosure will be clearly and completely described below with reference to the attached drawings in the embodiments of the present disclosure. All other embodiments obtained by those skilled in the related art based on the embodiments of the present disclosure without creative efforts shall fall within the scope of the protection of the present disclosure.

In the description of the present disclosure, it should be noted that the terms, such as “center”, “longitudinal”, “transverse”, “upper”, “lower”, “front”, “rear”, “left”, “right”, “vertical”, “horizontal”, “top”, “bottom”, “inner”, “outer”, etc., are merely used to facilitate describing the present disclosure and simplify the description, rather than indicating or implying that a device or an element referred to has a specific orientation, and is constructed and operated in a specific orientation, and therefore cannot be understood as a limitation to the present disclosure.

In addition, the terms, such as “first”, “second”, etc., do not denote any order, quantity, or importance, but are merely used to distinguish different elements. Similar words, such as “connected to” or “connected with”, do not define physical or mechanical connections, but may include electrical connections, optical connections, etc., whether direct connection or indirect connection.

It should be understood that the terminology used herein is for the purpose of describing particular embodiments only and is not intended to limit the present disclosure. It will be further understood that the terms, such as “including”, “containing”, when used in the present disclosure, are used to indicate the presence of stated features, integers, steps, elements, and/or exist, but do not preclude the presence or addition of one or more other features, integers, steps, elements, and/or combinations thereof.

Unless otherwise defined, all terms (including technical and scientific terms) used in the present disclosure have the same meaning as commonly understood by those skilled in the related art to which the present disclosure belongs. It should be further understood that the terms used in the present disclosure should be understood as having a meaning that is consistent with the meaning of these terms in the description and related fields of the present disclosure and should not be interpreted in an idealized or overly formal sense, except as expressly so defined in the present disclosure.

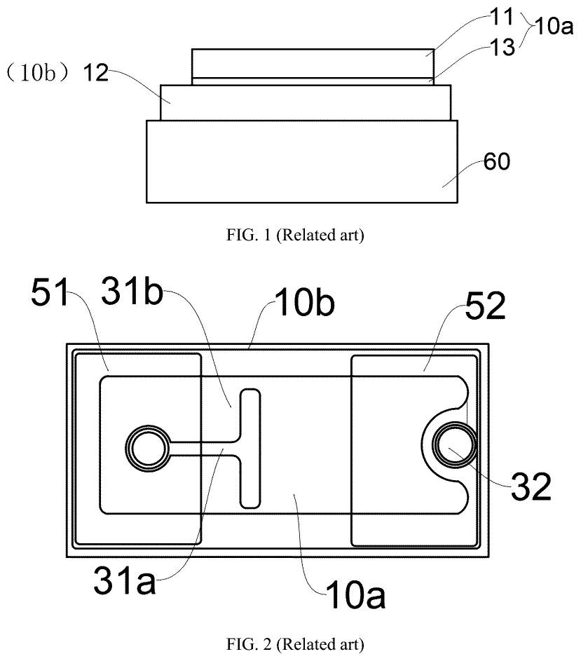

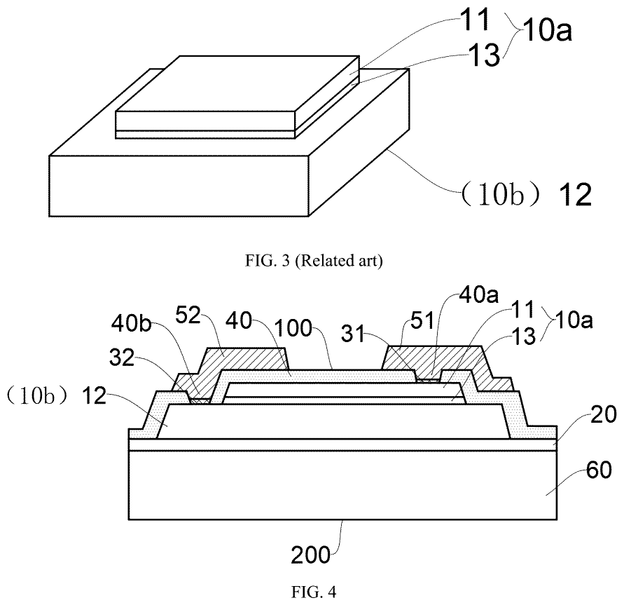

A flip-chip LED with a size of less than 300 μm in the related art, that is, the flip-chip LED with a side length less than 300 μm, belongs to a small-sized LED, and usually works under a low current of 0.01 mA to 1.5 mA. Specially, a structure of the flip-chip LED in the related art is shown in FIG. 1, which includes: an epitaxial structure; the epitaxial structure includes a first mesa 10a and a second mesa 10b sequentially stacked from top to bottom in that order; the first mesa 10a at least includes a first-type semiconductor layer 11 and an active layer 13; the second mesa 10b at least includes a second-type semiconductor layer 12; and an area of an upper surface of the second mesa 10b is greater than or equal to an area of a lower surface of the first mesa 10a. Moreover, as shown in FIG. 2 and FIG. 3, the first mesa 10a and the second mesa 10b are both rectangular structures.

When the above-mentioned small-sized LED works, due to a fact that a sidewall of the active layer of the LED is exposed too large, the problems of light absorption and non-radiative recombination caused by the defect of the sidewall are particularly prominent.

In order to mainly solve the above problems, the following embodiments are provided according to a design concept of the technical solutions of the present disclosure.

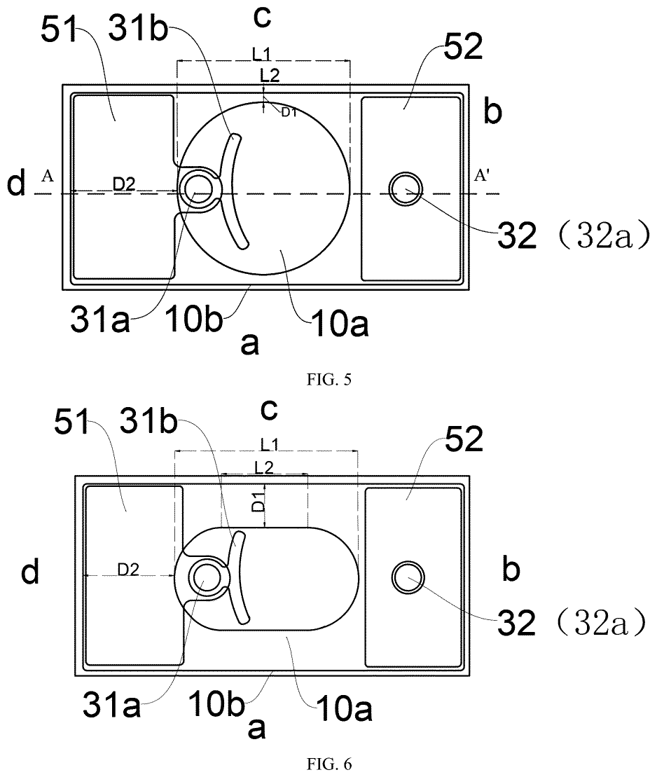

As shown in FIG. 4 and FIG. 5, an embodiment of the present disclosure provides a LED. The LED includes a first surface 100 and a second surface 200 that is opposite to the first surface 100; the first surface 100 includes a first side edge a, a second side edge b, a third side edge c, and a fourth side edge d that are sequentially connected in that order; and the four side edges can sequentially constitute a rectangle or a square, which is determined according to an actual product (i.e., the LED).

The LED according to the present disclosure further includes an epitaxial structure, which includes a first mesa 10a and a second mesa 10b that are sequentially stacked from top to bottom (i.e., from a top end to a bottom end of the epitaxial structure); the first mesa 10a at least includes: a first-type semiconductor layer 11 and an active layer 13, and the second mesa 10b at least includes: a second-type semiconductor layer 12; and an area of an upper surface of the second mesa 10b is greater than or equal to an area of a lower surface of the first mesa 10a.

In the present embodiment, specifically, the epitaxial structure is formed by growing on an original substrate by using methods such as metal organic chemical vapor deposition (MOCVD) or molecular-beam epitaxy (MBE) method. The original substrate is made from at least one selected from the group consisting of sapphire (i.e., Al₂O₃), silicon carbide (SiC), gallium arsenide (GaAs), gallium nitride (GaN), zinc oxide (ZnO), gallium phosphide (GaP), indium phosphide (InP), and germanium (Ge), and is not limited to the above. In the present embodiment, GaAs is selected to prepare the original substrate.

Specially, the first-type semiconductor layer 11 and the second-type semiconductor layer 12 are semiconductors with different types of conductivities, different electrical properties and polarities, which are doped with elements to provide electrons or electron holes. For example, when the first-type semiconductor layer 11 is a negative-type (N-type) semiconductor, the second-type semiconductor layer 12 is a positive-type (P-type) semiconductor, and the active layer 13 is formed between the first-type semiconductor layer 11 and the second-type semiconductor layer 12. Therefore, the electrons and the electron holes are driven by a current to be combined in the active layer 13, the electric energy of the current is converted into light energy to emit light, and a wavelength of the light emitted by the LED is adjusted by changing physical and chemical compositions of one or more layers of the epitaxial light-emitting layer (i.e., the epitaxial structure); and vice versa. In the present embodiment, the LED provided by the present disclosure determines the first-type semiconductor layer 11 as the N-type semiconductor and determines the second-type semiconductor layer 12 as the P-type semiconductor.

In view of the active layer 13, also referred to as the light-emitting layer or an activation layer, the active layer 13 is disposed between the first-type semiconductor layer 11 and the second-type semiconductor layer 12, which can convert the electrical energy into the light energy. The radiation light emitted by the active layer 13 can be red light or infrared light radiation.

Commonly used materials for the active layer 13 are aluminum gallium indium phosphide (AlGaInP) series materials, aluminum gallium indium nitride (AlGaInN) series materials, and zinc oxide (ZnO) series materials. The active layer 13 can be a single heterostructure (SH), a double heterostructure (DH), a double-sided double heterostructure (DDH), and a multi-quantum well (MQW). When the active layer 13 is made of the AlGaInP series material, the active layer 13 emits amber colored light such as red light, orange light, and yellow light by doping the semiconductors. Moreover, when the active layer 13 is made of the AlGaInN series material, the active layer 13 emits blue light or green light. In the present embodiment, the LED emits the red light or the infrared radiation.

In some embodiments, with reference to FIG. 4, the LED further includes a substrate 60. In a manufacturing process of the LED, the epitaxial structure grown on the original substrate is first provided, and then the epitaxial structure of the LED is bonded and transferred to the substrate 60, thereafter removing the original substrate for growing the epitaxial structure of the LED, that is, the bonding between the substrate 60 and the epitaxial structure is completed. The substrate 60 can be a conductive substrate or a non-conductive substrate, which can also be transparent or non-transparent. A bonding layer 20 is disposed between the substrate 60 and the epitaxial structure; specially, the bonding layer 20 is a single-layer structure or a composite-layer structure and is made of a conductive material or an insulation material. In an embodiment, with reference to FIG. 4, the substrate 60 and the epitaxial structure are bonded through the bonding layer 20, the bonding layer 20 is the single-layer structure or the composite-layer structure, a thickness of the bonding layer 20 is preferably in a range of 1 μm to 5 μm, the bonding layer 20 is made of the conductive material or the insulation material, and the bonding layer 20 can also be transparent or non-transparent. When the bonding layer 20 is the composite-layer structure, a bonding conductive layer and a bonding non-conductive layer are used to constitute the bonding layer 20; and the bonding non-conductive layer is closer to the substrate 60 relative to the bonding conductive layer. Further, the bonding conductive layer is a metal oxide containing at least one selected from zinc (Zn), indium (In), tin (Sn), and magnesium (Mg). In an illustrated embodiment, the material of the bonding conductive layer can be ZnO, indium (III) oxide (In₂O₃), stannic oxide (SnO₂), indium tin oxide (ITO), indium zinc oxide (IZO), gallium-doped zinc oxide (GZO), or any combination thereof. The material of the bonding non-conductive layer is determined as Al₂O₃, silicon dioxide (SiO₂), SiNₓ, magnesium fluoride (MgF₂), or titanium dioxide (TiO₂). It should be noted that the substrate 60 is not necessary, and in some embodiments, the substrate 60 can also be removed, for example, a micro-LED chip.

As shown in FIGS. 4-8, an area of a projection of the first mesa 10a on a plane where the first surface 100 is represented by s, and a perimeter-to-area ratio of the projection of the first mesa 10a is represented by γ, and the perimeter-to-area ratio γ of the first mesa 10a satisfies the following formula:

$$\frac{2 \sqrt{π s}}{s} \leq γ \leq \frac{2 ( ( \frac{s}{L 1} ) + L 1 )}{s}$$

In the above formula, L1 represents a projection length of an upper surface of the first mesa 10a on a plane passing through the first side edge a and perpendicular to the plane where the first surface 100 is located.

In the present embodiment, the perimeter-to-area ratio γ of the projection of the first mesa 10a on the plane where the first surface 100 is located is limited in a range.

Specially, when

$$γ = \frac{2 \sqrt{π s}}{s} ,$$

a cross section of the first mesa 10a is a circle, with reference to FIG. 5, the projection of the first mesa 10a on the plane where the first surface 100 is located is the circle; and at this time, under the same light-emitting area (i.e., under a condition that the areas of the upper surface and the lower surface of the first mesa 10a are specified), the perimeters of the upper and lower surfaces of the first mesa 10a are the smallest, and under a condition that a thickness of the first mesa 10a is specified, a side surface area of the first mesa 10a can be minimized, so that the exposed area of the sidewall is smaller, and the problems of light absorption and non-radiative recombination caused by the defect of the sidewall during the small-sized LED working at the low current are reduced.

Meanwhile, the perimeter-to-area ratio γ of the projection of the first mesa 10a is limited as

$$γ < \frac{2 ( ( \frac{s}{L 1} ) + L 1 )}{s} ;$$

and when

$$γ = \frac{2 ( ( \frac{s}{L 1} ) + L 1 )}{s} ,$$

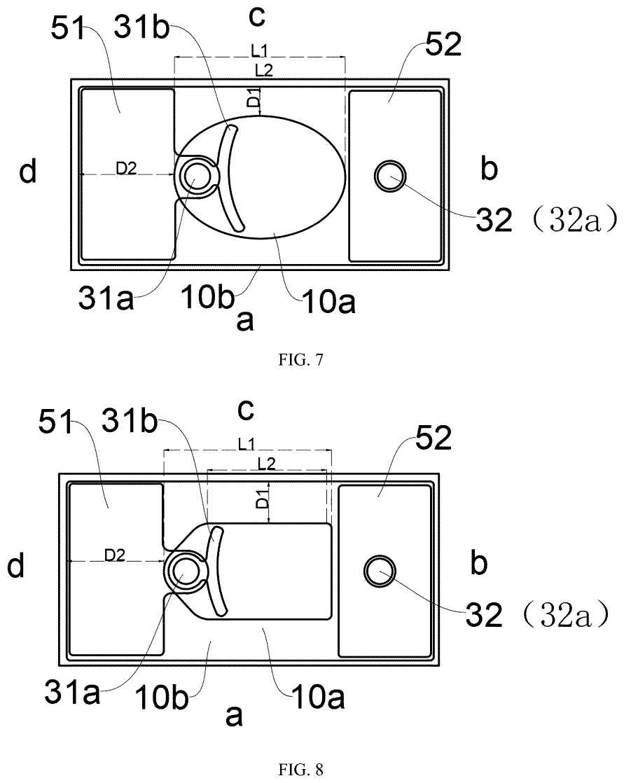

the perimeter-to-area ratio γ of the first mesa 10a adopts the γ value of the rectangular structure in the related art. In an illustrated embodiment, the projection of the first mesa 10a on the plane where the first surface 100 is located can be a combined pattern of an arc and a straight line, such as the projection of the first mesa 10a on the plane where the first surface 100 is located is determined as the combined pattern (with reference to FIG. 6 or FIG. 8), or the projection of the first mesa 10a on the plane where the first surface 100 is located is determined as an ellipse (with reference to FIG. 7). In these embodiments, the perimeter-to-area ratio γ of the first mesa 10a satisfies the formula:

$$\frac{2 \sqrt{π s}}{s} \leq γ \leq \frac{2 ( ( \frac{s}{L 1} ) + L 1 )}{s} ,$$

and these embodiments break through design limitations of the first mesa 10a in the small-sized LED, i.e., the first mesa 10a in the small-sized LED is the rectangular structure in the related art. Therefore, under the conditions that the light-emitting area is the same (that is, the areas of the upper and lower surfaces of the first mesa 10a are specified) and the thickness of the first mesa 10a is specified, the side surface area of the first mesa 10a can be smaller than that of the first mesa 10a in the related art, i.e., the first mesa 10a in the related art adopts the rectangular structure, so that the exposed area of the sidewall is smaller, and the problems of light absorption and non-radiative recombination caused by the defect of the sidewall during the small-sized LED working at the low current are reduced.

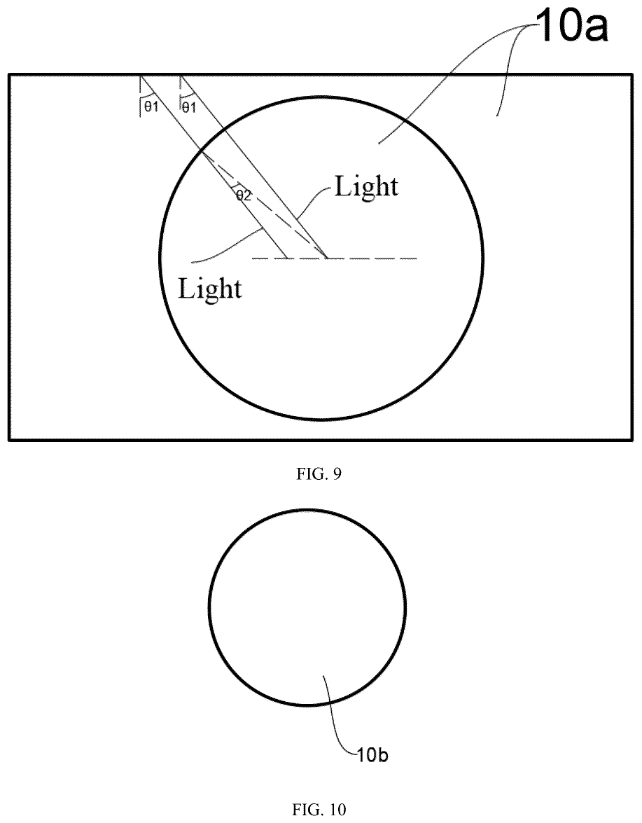

In addition, in the related art, as shown in FIG. 3, since the first mesa 10a is the rectangular structure, an incident angle θ₁ of the light emitted by the active layer 13 on the surface of the first mesa 10a is larger; due to the influence of refractive index of the material, a large part of the light is reflected back into the semiconductor again due to total reflection, and most of the light is absorbed by the semiconductor through multiple reflections, resulting in an extremely low light-extraction efficiency of the semiconductor. As shown in FIG. 9, FIG. 9 illustrates the schematic diagram of the optical path of the light, an incident angle θ₂ of the non-planar reflected light is obviously less than θ₁, so that the light is more possible to avoid total reflection at the surface of the first mesa 10a, thereby improving the light-emitting probability of the sidewall of the LED and further improving the external light-emitting efficiency of the LED.

With reference to FIGS. 5-8, on the basis of the above technical solution, in an illustrated embodiment, as viewed from a direction perpendicular to the first surface 100, a length of a part of a side edge of an outer contour of the upper surface of the first mesa 10a parallel to the first side edge a of the first surface 100 of the LED is represented by L2, L1 is greater than L2, and the at least one side of the projection of the first mesa 10a on the plane where the first surface 100 is located is the arc. As shown in FIG. 6, FIG. 7 and FIG. 8, L1 is greater than L2. Specially, as shown FIG. 5 and FIG. 7, the length of L2 is equal to 0. In the technical solution of the present embodiment, when L1 is greater than L2, the projection of the first mesa 10a on the plane where the first surface 100 of the LED is located is non-linear. Therefore, under the same light-emitting area, compared with the technical solution in the related art that the first mesa 10a is the rectangular structure, the side surface of the first mesa 10a in the present disclosure is smaller. Namely, under the same light-emitting areas of the upper and lower surfaces of the active layer, the sidewall of the first mesa 10a is exposed less, thereby reducing the problems of light absorption and non-radiative recombination caused by the defect of the sidewall during the small-sized LED working at the low current.

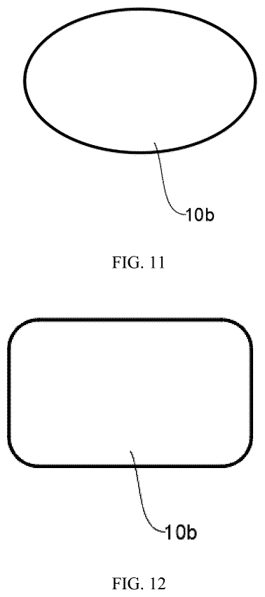

In some embodiments, with reference to FIG. 10, FIG. 11, and FIG. 12, a projection of the second mesa 10b on the plane where the first surface 100 of the LED is located is a circle or an ellipse or a rounded rectangle, and the designs of the second mesa 10b may be combined with the design of the first mesa 10a in any combination. Similarly, by adopting the above design for the second mesa 10b, the probability of decrease and consumption of the light emitted by the active layer 13 caused by the formation of total reflection inside the LED can be further reduced, thereby improving the external light-emitting efficiency of the LED.

Based on the above embodiment, a thickness of the first-type semiconductor layer 11 is in a range of 2 micrometers (μm) to 5 μm; a thickness of the active layer 13 is in a range of 0.02 μm to 0.07 μm; and a thickness of the second-type semiconductor layer 12 is in a range of 6 μm 11 μm. In the present embodiment, by controlling the epitaxial growth process, the thickness of the epitaxial structure is further reduced, resulting in a decrease in the thickness of the first mesa 10a. Therefore, the defect of area exposed on the sidewall decreases, and the number of defects between the epitaxial film layers also decreases, thereby reducing the problems of light absorption and non-radiative recombination caused by the defect of the sidewall during the LED working at the low current.

In some embodiments, a ratio of the area of the projection of the first mesa 10a on the plane where the first surface 100 is located to the area of the projection of the second mesa 10b on the plane where the first surface 100 is located is in a range of 0.02 to 0.6. The above design scheme enables the chip (i.e., the LED) to maintain stable external quantum efficiency by injecting current density into the active layer 13 within an appropriate operating range under the low current (i.e., 0.01 mA to 1 mA) driving, while avoiding a significant decrease in external quantum efficiency due to low current density.

In some embodiments, with reference to FIGS. 5-8, the first side a, the second side b, the second side c, and the fourth side d are sequentially connected in that order to form a rectangle. Specially, in the rectangle, a length of the first side edge a is equal to a length of the third side edge c, a length of the second side edge b is equal to a length of the fourth side edge d, and the length of the first side edge a is greater than the length of the second side edge b. Moreover, a minimum distance from a portion in an outer contour of the upper surface of the second mesa 10b closet to the first side edge a or the third side edge c of the first surface 100 to a side edge of the upper surface of the first mesa 10a is represented by D1; a minimum distance from a portion in the outer contour of the upper surface of the second mesa 10b closet to the second side edge b or the fourth side edge d of the first surface 100 to the side edge of the upper surface of the first mesa 10a is represented by D2; and D1 is less than D2.

Further, a minimum distance from the side edge of the upper surface of the first mesa 10a to the first side edge a or the third side edge c of the first surface 100 is in a range of 2 μm to 6 μm.

In some embodiments, in the above technical solution or combination scheme, it is preferable to consider a small-sized flip-chip LED with a size range of less than 300 μm.

In the above solution and a combination thereof, the present disclosure further provides another technical solution, with reference to FIG. 4 to FIG. 8, the first-type semiconductor layer 11 is provided with a first contact electrode 31 thereon, the first contact electrode 31 includes: a first dot electrode 31a and two first extension portions 31b, and the two first extension portions 31b respectively extend towards different side edges of the LED from the first dot electrode 31a. Through the above design, the current can be diffused more uniformly in the light-emitting area, thereby improving the uniformity of light emission.

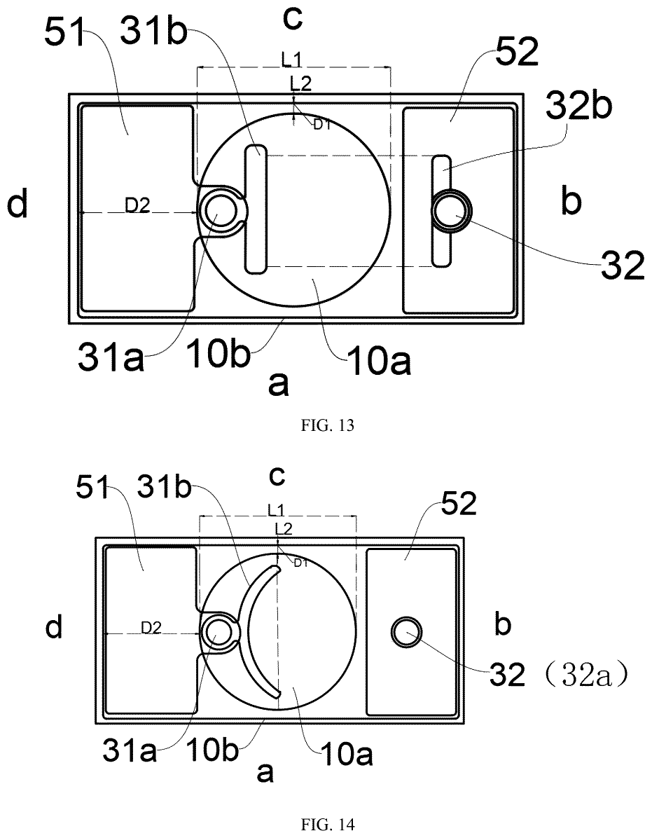

In some embodiments, the two first extension portions 31b may form a straight-line segment (with reference to FIG. 13) or form an arc-shaped segment (with reference to FIG. 5 and FIG. 14).

When the two first extension portions 31b form the arc-shaped segment, as shown in FIG. 14, two ends of a projection of the arc-shaped segment on the first surface 100 are located on a centerline of the projection of the first mesa 10a on the first surface 100. Further, in the embodiment of the present disclosure, the upper surface of the first mesa 10a is the circle, the two first extension portions 31b form the arc-shaped segment that can better match the shape of the first mesa 10a, thereby reducing diffusion of the current in a non-uniform corner region of the light-emitting area, and further improving uniform diffusion of the current in the light-emitting area. The two ends of the projection of the arc-shaped segment on the first surface 100 are located on the center line of the projection of the first mesa on the first surface 100, so that the current can be more conveniently diffused between different electrodes of the LED.

In some embodiments, the second-type semiconductor layer 12 is provided with a second contact electrode 32 thereon, which can be combined with the electrode shape of the first contact electrode 31; and as shown in FIG. 5 and FIG. 14, the second contact electrode 32 is a dot electrode, which can be combined with a solution in which the two first extension portions 31b form the arc-shaped segment.

In another embodiment of the present disclosure, as shown in FIG. 13, the second contact electrode 32 includes a second dot electrode 32a and two second extension portions 32b. The two second extension portions 32b respectively extend towards different side edges of the LED from the second dot electrode 32a. Moreover, as shown in FIG. 13, in a plane perpendicular to the first surface 100 of the LED and passing through the fourth side edge d, a projection length of the second contact electrode 32 on the plane perpendicular to the first surface 100 of the LED and passing through the fourth side edge d is less than a projection length of the first contact electrode 31 on the plane perpendicular to the first surface 100 of the LED and passing through the fourth side edge d. Therefore, through the above technical solution, the light-emitting efficiency and the anti-electro-static discharge (ESD) capability of the flip-chip LED can be effectively improved.

In the present embodiment, when the first-type semiconductor layer 11 is the N-type semiconductor, the second-type semiconductor layer 12 is the P-type semiconductor.

In some embodiments, as shown in FIG. 4, the epitaxial structure of the LED includes a first mesa 10a and a second mesa 10b that are sequentially stacked from top to bottom in that order. The first mesa 10a at least includes: a first-type semiconductor layer 11 and an active layer 13, and the second mesa 10b at least includes a second-type semiconductor layer 12. An area of an upper surface of the second mesa 10b is greater than or equal to an area of a lower surface of the first mesa 10a. The LED further includes an insulation protection layer 40 disposed on the upper surface of the first mesa 10a and the sidewall of the epitaxial structure. A first pad electrode 51 and a second pad electrode 52 are disposed above the insulation protection layer 40.

The insulation protection layer 40 defines a first opening 40a and a second opening 40b.

In the present embodiment, the insulation protection layer 40 is made of a non-conductive material selected from an inorganic oxide or a nitride, or silicon dioxide, silicon nitride, titanium oxide, tantalum oxide, niobium oxide, barium titanium trioxide (BaTiO₃), magnesium fluoride, aluminum oxide, or a combination thereof, and the combination thereof can be, for example, a distributed Bragg reflector (DBR) formed by repeatedly stacking two materials of the above inorganic oxide or the nitride.

In an illustrated embodiment, with reference to FIG. 4 and FIG. 5, FIG. 4 illustrates the schematic cross-sectional view of the LED illustrated in FIG. 5 along the section line A-A′ shown in FIG. 5, the first contact electrode 31 is disposed between the first pad electrode 51 and the first-type semiconductor layer 11, and the second contact electrode 32 is disposed between the second pad electrode 52 and the second-type semiconductor layer 12.

As viewed from a direction perpendicular to the first surface 100, the first opening 40a is disposed to expose a part of the first-type semiconductor layer 11, and the first pad electrode 51 is filled into the first opening 40a to be in direct contact with the first-type semiconductor layer 11 for electrical connection or ohmic connection with the first-type semiconductor layer 11 through the first contact electrode 31, and the first pad electrode 51 covers the first opening 40a. Meanwhile, the second opening 40b is disposed to expose a part of the second-type semiconductor layer 12, and the second pad electrode 52 is filled into the second opening 40b to be in direct contact with the second-type semiconductor layer 12 for electrical connection or ohmic connection with the second-type semiconductor layer 12 through the second contact electrode 32. The first pad electrode 51 and the second pad electrode 52 partially cover the insulation protection layer 40, and partial regions of the first pad electrode 51 and the second pad electrode 52 overlap the active layer 13 respectively.

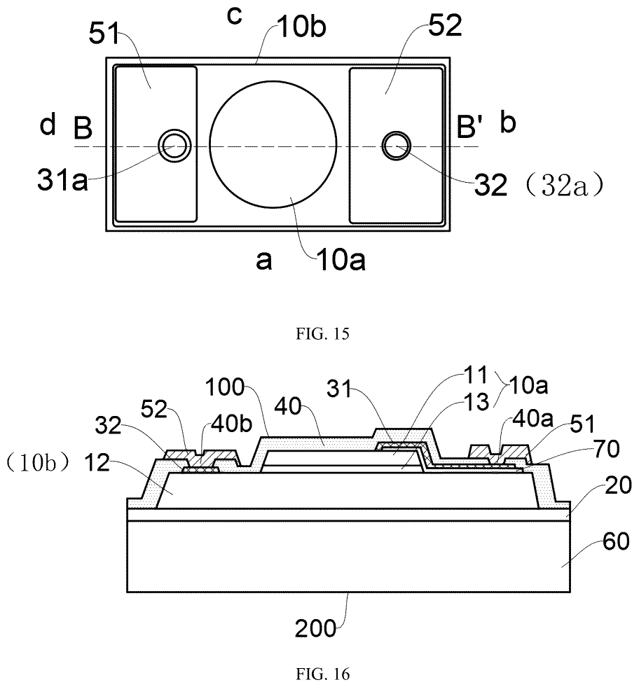

In an alternative embodiment of the present disclosure, with reference to FIG. 15 and FIG. 16, FIG. 16 illustrates the schematic cross-sectional view of the LED illustrated in FIG. 15 along the section line B-B′ shown in FIG. 15, and the first pad electrode 51 and the second pad electrode 52 are completely disposed outside the active layer 13. Specially, the second opening 40b exposes a portion of the second-type semiconductor layer 12, the second pad electrode 52 is filled into the second opening 40b to be in direct contact with the second-type semiconductor layer 12 for electrical connection or ohmic connection with the second-type semiconductor layer 12 through the second contact electrode 32, and the second contact electrode 32 is completely disposed below the second pad electrode 52. Meanwhile, the first opening 40a is disposed above the second-type semiconductor layer 12, a portion of the first contact electrode 31 is disposed above the second-type semiconductor layer 12, and another portion of the first contact electrode 31 is disposed above the first-type semiconductor layer 11 and is electrically connected to the first-type semiconductor layer 11. In the present embodiment, the LED further includes an electricity-insulation layer 70, and the electricity-insulation layer 70 is disposed between the first contact electrode 31 and the active layer 13, as well as between the first contact electrode 31 and the second-type semiconductor layer 12, to prevent the first contact electrode 31 from contacting the active layer 13 and the second-type semiconductor layer 12, thereby preventing the short circuit. Moreover, the first pad electrode 51 is filled into the first opening 40a to be in contact with the first contact electrode 31 to be electrically connected to the first-type semiconductor layer 11, and the first pad electrode 51 is disposed to cover the first opening 40a. Therefore, the first pad electrode 51 and the second pad electrode 52 are completely disposed outside the active layer 13, thereby improving the light-emitting efficiency of the LED.

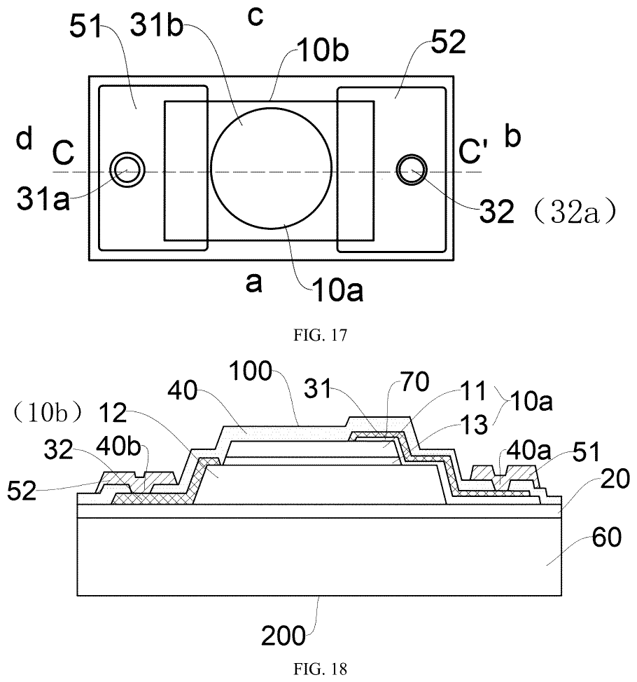

In view of that the first pad electrode 51 and the second pad electrode 52 are completely disposed outside the active layer 13, the disclosure further provides another embodiment, as shown in FIG. 17 and FIG. 18, FIG. 18 illustrates the schematic cross-sectional view of the LED illustrated in FIG. 17 along the section line C-C′ shown in FIG. 17. Specifically, as viewed from the direction perpendicular to the first surface 100, the first pad electrode 51 and the second pad electrode 52 are completely disposed outside the epitaxial structure. Moreover, the first opening 40a is disposed above the bonding layer 20 (if the substrate 60 is not equipped with the bonding layer 20, the substrate 60 is used as the substitution), a portion of the first contact electrode 31 is disposed above the bonding layer 20 and below the first opening 40a, another portion of the first contact electrode 31 is disposed above the first-type semiconductor layer 11 and electrically connected to the first-type semiconductor layer 11. In addition, the LED also includes the electricity-insulation layer 70. The electricity-insulation layer 70 is disposed between the first contact electrode 31 and the active layer 13, between the first contact electrode 31 and the second-type semiconductor layer 12, as well as between the first contact electrode 31 and the bonding layer 20 to avoid the short circuit caused by the contact between the first contact electrode 31 and the active layer 13 as well as the second-type semiconductor layer 12. Furthermore, the first pad electrode 51 is filled into the first opening 40a and is electrically connected to the first-type semiconductor layer 11 through the first contact electrode 31, and the first pad electrode 51 is disposed to cover the first opening 40a.

Meanwhile, the second opening 40b is disposed above the bonding layer 20 (if the substrate 60 is not equipped with the bonding layer 20, the substrate 60 is used as the substitution), a portion of the second contact electrode 32 is disposed above the bonding layer 20 and below the second opening 40b, another portion of the second contact electrode 32 is disposed above the second-type semiconductor layer 12 and is electrically connected to the second-type semiconductor layer 12, and the first pad electrode 51 is filled into the first opening 40a to be in contact with the first contact electrode 31 and covers the first opening 40a, so as to be electrically connected to an upper portion of the second-type semiconductor layer 12.

In an embodiment, as shown in FIG. 16, a bottom width of the first opening 40a is less than or equal to a bottom width of the first contact electrode 31, and a bottom width of the second opening 40b is less than or equal to a bottom width of the second contact electrode 32.

In an embodiment, a projection of the substrate 60 on the plane where the first surface 100 is located is a circle or an ellipse or a rounded rectangle. Similarly, through the shape design of the substrate 60, the probability that the light emitted by the active layer 13 is reduced due to total reflection inside the LED can be further reduced, thereby improving the external light-emitting efficiency of the LED.

The present disclosure further provides an embodiment of a LED, with reference to FIG. 4, the LED includes a first surface 100 and a second surface 200 that is disposed opposite to the first surface 100, and the first surface 100 includes a first side edge a, a second side edge b, a third side edge c, and a fourth side edge d that are sequentially connected in that order.

The LED further includes: an epitaxial structure, and the epitaxial structure includes: a first mesa 10a and a second mesa 10b that are sequentially stacked from top to bottom end in that order; the first mesa 10a at least includes: a first-type semiconductor layer 11 and an active layer 13, and the second mesa 10b at least includes: a second-type semiconductor layer 12; and an area of an upper surface of the second mesa 10b is greater than or equal to an area of a lower surface of the first mesa 10a.

With reference to FIGS. 4-8, in the LED with a size of less than 300 μm, at least one side edge of a projection of the first mesa 10a on a plane where the first surface 100 is located is an arc, and a protrusion portion of the arc faces towards a side edge of the first surface 100 of the LED closer to the arc.

In the technical solution of the present embodiment, the projection of the first mesa 10a on the plane where the first surface 100 is located is the arc, that is, the side edge of the first mesa 10a is an arc surface, or a projection of the side surface of the first mesa 10a on the plane where the first surface 100 of the LED is located is in a non-linear shape. Specially, the projection of the first mesa 10a on the plane where the first surface 100 is located can be a combination of an arc and a straight line, such as a combination of an arc and a straight line (with reference to FIG. 6 and FIG. 8), or an ellipse (with reference to FIG. 7). Through the above design limitations, the area of the side surface of the first mesa 10a is smaller compared to the technical solution in the related art where the first mesa 10a is a rectangle under the same light-emitting area. That is, under the same light-emitting area of the active layer 13, the side surface of the first mesa 10a is exposed less, thereby reducing the problems of light absorption and non-radiative recombination caused by the defect of the sidewall during the small-sized LED working at the low current.

The present disclosure further provides an embodiment of a light-emitting device, which adopts the LED according to any of the above embodiments or the illustrated technical solution or the combination of the embodiments. Furthermore, the present disclosure utilizes the red light or the infrared radiation or blue light or green radiation provided by the LED for corresponding display or illumination or utilizes other optical devices.

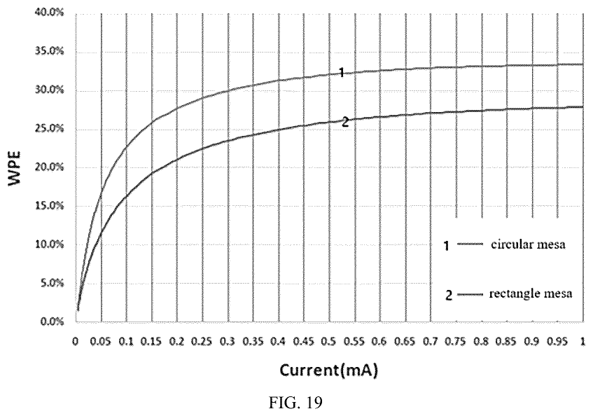

The present disclosure further provides an optical test according to an embodiment, as shown in FIG. 5, of the present disclosure, a specification of the LED in the present test embodiment is 3.5×6 square millimeters (mil²), the projection of the first mesa 10a on the plane where the first surface 100 is located is the circle, the two first extension portions 31b form the arc-shaped segment, and the second contact electrode 32 is the dot electrode. The optical test, i.e., an external quantum efficiency test (illustrated as wall-plug efficiency abbreviated WPE in FIG. 19) is performed on the product (i.e., the LED with the fist mesa 10a being the circle) of the present embodiment and the chip with the same specification (i.e., a LED with the fist mesa 10a being the rectangle), as shown in FIG. 19, the test result shows that the light-emitting efficiency of the circular mesa design chip is greatly improved compared with that of a rectangular-structure design chip under the driving of the small current (i.e., 0.01 mA-1 mA).

Finally, it should be noted that the above embodiments are only used to illustrate the technical solutions of the present disclosure and are not limited thereto. Although the present disclosure is described in detail with reference to the foregoing embodiments, those skilled in the related art should understand that the technical solutions described in the foregoing embodiments may still be modified, or some or all of the technical features may be equivalently replaced. However, these modifications or replacements do not make the essence of the corresponding technical solutions deviate from the scope of the technical solutions of the various embodiments of the present disclosure.

What is claimed is:

1. A light-emitting diode (LED), comprising: a first surface (100) and a second surface (200) disposed opposite to the first surface (100);
wherein the first surface (100) comprises a first side edge (a), a second side edge (b), a third side edge (c), and a fourth side edge (d), which are sequentially connected in that order;
wherein the LED further comprises: an epitaxial structure, and the epitaxial structure comprises: a first mesa (10a) and a second mesa (10b), which are sequentially stacked from top to bottom in that order; the first mesa (10a) at least comprises: a first-type semiconductor layer (11) and an active layer (13), and the second mesa (10b) at least comprises: a second-type semiconductor layer (12); and an area of an upper surface of the second mesa (10b) is greater than or equal to an area of a lower surface of the first mesa (10a);
wherein an area of a projection of the first mesa (10a) on a plane where the first surface (100) is located is represented by s, and a perimeter-to-area ratio of the projection of the first mesa (10a) is represented by γ, and the perimeter-to-area ratio γ of the first mesa (10a) satisfies the following formula:
$$\frac{2 \sqrt{π s}}{s} \leq γ \leq \frac{2 ( ( \frac{s}{L 1} ) + L 1 )}{s}$$
wherein L1 represents a projection length of an upper surface of the first mesa (10a) on a plane passing through the first side edge (a) and perpendicular to the plane where the first surface (100) is located.

2. The LED according to claim 1, wherein a thickness of the first-type semiconductor layer (11) is in a range of 2 micrometers (μm) to 5 μm; a thickness of the active layer (13) is in a range of 0.02 μm to 0.07 μm; a thickness of the second-type semiconductor layer (12) is in a range of 3 μm to 11 μm; and a size of the LED is less than 300 μm.

3. The LED according to claim 1, wherein a ratio of the area of the projection of the first mesa (10a) on the plane where the first surface (100) is located to an area of a projection of the second mesa (10b) on the plane where the first surface (100) is located is in a range of 0.02 to 0.6.

4. The LED according to claim 1, wherein as viewed from a direction perpendicular to the first surface (100), a length of a part of a side edge of an outer contour of the upper surface of the first mesa (10a) parallel to the first side edge (a) of the first surface (100) of the LED is represented by L2, L1 is greater than L2, and at least one side of the projection of the first mesa (10a) on the plane where the first surface (100) is located is an arc.

5. The LED according to claim 1, wherein the projection of the first mesa (10a) on the plane where the first surface (100) is located is a circle or an ellipse or a combined pattern of an arc and a straight line.

6. The LED according to claim 1, wherein a projection of the second mesa (10b) on the plane where the first surface (100) of the LED is located is a circle or an ellipse or a rounded rectangle.

7. The LED according to claim 1, wherein a length of the first side edge (a) is equal to a length of the third side edge (c), a length of the second side edge (b) is equal to a length of the fourth side edge (d), and the length of the first side edge (a) is greater than the length of the second side edge (b);
wherein a minimum distance from a portion in an outer contour of the upper surface of the second mesa (10b) closet to the first side edge (a) or the third side edge (c) of the first surface (100) to a side edge of the upper surface of the first mesa (10a) is represented by D1;
wherein a minimum distance from a portion in the outer contour of the upper surface of the second mesa (10b) closet to the second side edge (b) or the fourth side edge (d) of the first surface (100) to the side edge of the upper surface of the first mesa (10a) is represented by D2;
wherein D1 is less than D2; and
wherein a minimum distance from the side edge of the upper surface of the first mesa (10a) to the first side edge (a) or the third side edge (c) of the first surface (100) is in a range of 2 μm to 6 μm.

8. The LED according to claim 1, wherein the first-type semiconductor layer (11) is provided with a first contact electrode (31) thereon, the first contact electrode (31) comprises: a first dot electrode (31a) and two first extension portions (31b), and the two first extension portions (31b) respectively extend towards different side edges of the LED from the first dot electrode (31a); and the two first extension portions (31b) form a straight-line segment or an arc-shaped segment.

9. The LED according to claim 8, wherein when the two first extension portions (31b) form the arc-shaped segment, two ends of a projection of the arc-shaped segment on the first surface (100) are located on a centerline of the projection of the first mesa (10a) on the first surface (100).

10. The LED according to claim 1, wherein the second-type semiconductor layer (12) is provided with a second contact electrode (32) thereon, the second contact electrode (32) is a dot electrode, or the second contact electrode (32) comprises: a second dot electrode (32a) and two second extension portions (32b), and the two second extension portions (32b) respectively extend towards different side edges of the LED from the second dot electrode (32a).

11. The LED according to claim 10, wherein in a plane perpendicular to the first surface (100) of the LED and passing through the fourth side edge (d), a projection length of the second contact electrode (32) on the plane perpendicular to the first surface (100) of the LED and passing through the fourth side edge (d) is less than a projection length of the first contact electrode (31) on the plane perpendicular to the first surface (100) of the LED and passing through the fourth side edge (d).

12. The LED according to claim 1, further comprising: an insulation protection layer (40) disposed on the upper surface of the first mesa (10a) and a sidewall of the epitaxial structure;
wherein a first pad electrode (51) and a second pad electrode (52) are disposed above the insulation protection layer (40); and
wherein the insulation protection layer (40) defines a first opening (40a) and a second opening (40b) thereon; the first pad electrode (51) is filled into the first opening (40a) to be electrically connected to the first-type semiconductor layer (11); and the second pad electrode (52) is filled into the second opening (40b) to be electrically connected to the second-type semiconductor layer (12).

13. The LED according to claim 12, wherein a first contact electrode (31) is disposed between the first pad electrode (51) and the first-type semiconductor layer (11), and a second contact electrode (32) is disposed between the second pad electrode (52) and the second-type semiconductor layer (12).

14. The LED according to claim 13, wherein a bottom width of the first opening (40a) is less than or equal to a bottom width of the first contact electrode (31), and a bottom width of the second opening (40b) is less than or equal to a bottom width of the second contact electrode (32).

15. The LED according to claim 12, wherein as viewed from a direction perpendicular to the first surface (100), partial regions of the first pad electrode (51) and the second pad electrode (52) overlap the active layer (13) respectively, or the first pad electrode (51) and the second pad electrode (52) are disposed outside the active layer (13).

16. The LED according to claim 1, further comprising: a substrate (60) and a bonding layer (20);
wherein the bonding layer (20) is disposed between the substrate (60) and the epitaxial structure; and
wherein the bonding layer (20) is a single-layer structure or a composite-layer structure and is made of a conductive material or an insulation material.

17. The LED according to claim 1, wherein a thickness of the bonding layer (20) is in a range of 1 μm to 5 μm.

18. The LED according to claim 1, wherein a projection of the substrate (60) on the plane where the first surface (100) is located is a circle or an ellipse or a rounded rectangle.

19. A LED, comprising: a first surface (100) and a second surface (200) disposed opposite to the first surface (100);
wherein the first surface (100) comprises a first side edge (a), a second side edge (b), a third side edge (c), and a fourth side edge (d), which are sequentially connected in that order;
wherein the LED further comprises: an epitaxial structure, and the epitaxial structure comprises: a first mesa (10a) and a second mesa (10b) sequentially stacked from top to bottom in that order;
wherein the first mesa (10a) at least comprises: a first-type semiconductor layer (11) and an active layer (13), and the second mesa (10b) at least comprises: a second-type semiconductor layer (12); and an area of an upper surface of the second mesa (10b) is greater than or equal to an area of a lower surface of the first mesa (10a); and
wherein a size of the LED is less than 300 μm, at least one side edge of a projection of the first mesa (10a) on a plane where the first surface (100) is located is an arc, and a protrusion portion of the arc faces towards a side edge of the first surface (100) of the LED closer to the arc.

20. A light-emitting device, comprising the LED according to claim 1.
